(19) United States
(12) Patent Application Publication
(10) Pub. No.: US 2017/0331029 A1
(43) Pub. Date: Nov. 16, 2017

(54) SENSOR DEVICE FOR SENSOR NETWORKS AND METHOD FOR TRANSMITTING DATA TO SENSOR NETWORK

(71) Applicant: TOHOKU UNIVERSITY, Sendai-shi, Miyagi (JP)

(72) Inventors: Tomokatsu KONNO, Sendai-shi (JP); Motoaki HARA, Sendai-shi (JP); Hiroki KUWANO, Sendai-shi (JP)

(73) Assignee: SENDAI SMART MACHINES CO., LTD., Sendai-shi, Miyagi (JP)

(21) Appl. No.: 15/512,770

(22) PCT Filed: Sep. 10, 2015
(86) PCT No.: PCT/JP2015/075774

§ 371 Date: Mar. 20, 2017

(30) Foreign Application Priority Data
Sep. 18, 2014 (JP) 2014-190546

(51) Int. Cl. H01L 41/113; H04L 12/26

(52) U.S. Cl. CPC H01L 41/1132; H04L 43/08; H04L 43/50

(57) ABSTRACT

A sensor device for sensor networks capable of saving power and securing accuracy and a method for transmitting data to a sensor network. The device includes: an oscillation-type sensor that oscillates with a mechanical vibrator; a data processor and communicator that processes a signal output from the oscillation-type sensor and transmits data to an external apparatus; a power supply that supplies electric power to the oscillation-type sensor and the data processor and communicator; and a power supply control unit that controls connection of a power supply line between the power supply and the oscillation-type sensor and connection of a power supply line between the power supply and the data processor and communicator. The power supply control unit connects the power supply line between the power supply and the oscillation-type sensor and then connects the power supply line between the power supply and the data processor and communicator.

### TECHNICAL FIELD

The present invention relates to a sensor device for sensor networks capable of saving power while maintaining accuracy and a method for transmitting data to a sensor network.

### BACKGROUND ART

Sensor networks are promising as an ICT (Information and Communication Technology) system in which the states of human, objects, environment, energy, and the like are recognized by various sensors, the signal output from the sensors are circulated as information, and the relations between the signals are analyzed so that the state can be understood on a real-time basis and predictions can be provided on the basis of analysis of time-series information.

In recent years, for example, deterioration of structures of a transportation system such as bridges, tunnels, highways, and railroads has become an issue. This deterioration causes partial delamination, falling, collapse, and the like of a structure and causes serious damage. Due to this, appropriate maintenance is indispensable for structures of a transportation system. However, artificial monitoring and maintenance is not a sufficient measure for performing periodic health diagnosis of the structures of the transportation system at an appropriate timing.

The following measures have been taken to solve such a problem. That is, sensors are distributed to a structure of a transportation system to construct a network system. By doing so, detailed information on the structure of the transportation system is acquired and used for monitoring and maintenance (for example, see Patent Documents 1 to 3). In order to construct such a network system, development of a wireless sensor node for wirelessly communicating the information acquired from sensors is important.

A wireless sensor node generally includes a sensor, a sensor peripheral circuit, a processing circuit, a communication circuit, and other processing circuits, and a power control unit. The wireless sensor node generally operates intermittently to save power.

In order to achieve power-saving, sensors which use mechanical vibration have been applied (Non-Patent Document 1). These sensors use resonance and meet lower power consumption and high sensitivity by exciting efficient mechanical vibration. The present inventors have tried to incorporate such sensors into a wireless sensor node (Non-Patent Document 2).

In Non-Patent Document 2, an oscillator which uses a mechanical vibrator as a frequency reference is used as a sensor to realize an output in a frequency region and to enhance noise resistance.

### CITATION LIST

### Patent Document

Patent Document 1: Japanese Patent Application Laid-Open No. 2008-255572
Patent Document 2: Japanese Patent Application Laid-Open No. 2005-353015
Patent Document 3: Japanese Patent Application Laid-Open No. 2004-301571

### Non-Patent Document

Non-Patent Document 1: Z Bao et. al. “Experimental Study of Highly Sensitive Sensor Using a Surface Acoustic Wave Resonator for Wireless Strain Detection”, 51,07GC23
Non-Patent Document 2: T. Konno et. al. “Oscillator-based strain gauges employing surface acoustic wave resonators for wireless sensor network”, In Proc. International Ultrasonic Symposium 2013, pp. 1930

### SUMMARY OF INVENTION

### Problems to be Solved by Invention

However, when an intermittent operation is performed using such an oscillation-type sensor as disclosed in Non-Patent Document 2, it takes a considerable time until the oscillator is activated and stabilized, and it is difficult to save power while maintaining accuracy.

Therefore, an object of the present invention is to provide a sensor device for sensor networks capable of saving power while maintaining accuracy and a method for transmitting data to a sensor network.

### Solutions to Problems

In order to attain the object, the present invention employs the following means.

[1] A sensor device for sensor networks, including:

an oscillation-type sensor that oscillates with a mechanical vibrator;

a data processor and communicator that processes a signal output from the oscillation-type sensor and transmits data to an external apparatus;

a power supply that supplies electric power to the oscillation-type sensor and the data processor and communicator; and

a power supply control unit that controls connection of a power supply line between the power supply and the oscillation-type sensor and connection of a power supply line between the power supply and the data processor and communicator, wherein

the power supply control unit connects the power supply line between the power supply and the oscillation-type sensor and then connects the power supply line between the power supply and the data processor and communicator.

[2] The sensor device for sensor networks according to [1], further including:

a monitoring unit that monitors an oscillation state of the oscillation-type sensor, wherein

the power supply control unit connects the power supply line between the power supply and the data processor and communicator according to a monitoring state obtained by the monitoring unit.

[3] The sensor device for sensor networks according to [1] or [2], further including:
another monitoring unit that monitors an activation state of the data processor and communicator, wherein
the other monitoring unit instructs the data processor and communicator to start performing data communication with a sensor network when an activation state of the data processor and communicator and a communication connection state with the sensor network are confirmed.
   [4] The sensor device for sensor networks according to any one of [1] to [3], wherein

upon receiving an instruction via a sensor network, the power supply control unit starts connecting the power supply line between the power supply and the oscillation-type sensor.

[5] The sensor device for sensor networks according to [1], wherein

the data processor and communicator includes a data processor that processes the signal output from the oscillation-type sensor and a communicator that transmits data input from the data processor to the external apparatus, and

the power supply control unit controls the power supply line between the power supply and the data processor and the power supply line between the power supply and the communicator separately.

[6] The sensor device for sensor networks according to any one of [1] to [5], wherein

the oscillation-type sensor is a surface acoustic wave sensor.

[7] The sensor device for sensor networks according to any one of [1] to [6], wherein

the mechanical vibrator is a crystal oscillator or a piezoelectric thin film oscillator.

[8] A method for transmitting data to a sensor network, including:

when a sensor device for sensor networks including an oscillation-type sensor that oscillates with a mechanical vibrator and a data processor and communicator that processes a signal output from the oscillation-type sensor and transmits the signal to an external apparatus transmits data to a sensor network,

activating the oscillation-type sensor;

activating the data processor and communicator after oscillation of the oscillation-type sensor is stabilized, and

allowing the data processor and communicator to process the signal output from the oscillation-type sensor to transmit the data to the sensor network when an activation state of the data processor and communicator and a communication connection state with the sensor network are confirmed.

[9] A method for transmitting data to a sensor network, including:

when a sensor device for sensor networks including an oscillation-type sensor that oscillates with a mechanical vibrator, a data processor that processes a signal output from the oscillation-type sensor, and a communicator that transmits data input from the data processor to an external apparatus transmits data to a sensor network,

activating the oscillation-type sensor;

activating any one of the data processor and the communicator after oscillation of the oscillation-type sensor is stabilized; and

activating the communicator or the data processor which is not activated when an activation state of anyone of the data processor and the communicator is confirmed and allowing the data processor to process the signal output from the oscillation-type sensor to transmit the data to the sensor network via the communicator when the activation is confirmed.

### Effects of the Invention

According to the present invention, when the oscillation-type sensor is activated and the oscillation of the oscillation-type sensor is stabilized, the data processor and communicator, the data processor, or the communicator is activated. Therefore, the data processor and communicator, the data processor, or the communicator can save power without consuming unnecessary electric power until the oscillation of the oscillation-type sensor is stabilized. Moreover, unless the oscillation-type sensor is stabilized, since the data processor and communicator, the data processor, or the communicator is not activated, the sensor information is not transmitted to the external apparatus wastefully and low-accuracy data is not transmitted to the external apparatus.

### BRIEF DESCRIPTION OF DRAWINGS

FIG. 1 is a diagram illustrating a configuration of a sensor device for sensor networks according to an embodiment of the present invention.

FIG. 2 is a diagram illustrating an example of a sensor network constructed using the sensor device for sensor networks according to the embodiment of the present invention.

FIG. 3 is a flowchart of a method for transmitting data to a sensor network according to an embodiment of the present invention.

FIG. 4(a) is a diagram illustrating a portion of STEP4 illustrated in FIG. 3 and FIG. 4(b) is a diagram illustrating a remaining portion thereof.

FIG. 5 is a diagram illustrating a configuration of the sensor device for sensor networks according to the embodiment of the present invention, the configuration being different from that illustrated in FIG. 1.

FIG. 6 is a flowchart of the method for transmitting data to the sensor network according to the embodiment of the present invention, the flowchart being different from that illustrated in FIG. 3.

FIG. 7 is a flowchart of the method for transmitting data to the sensor network according to the embodiment of the present invention, the flowchart being different from those illustrated in FIGS. 3 and 6.

### MODE FOR CARRYING OUT THE INVENTION

Hereinafter, modes for carrying out the present invention will be described with reference to the drawings.

### [Basic Configuration of Sensor Device for Sensor Networks]

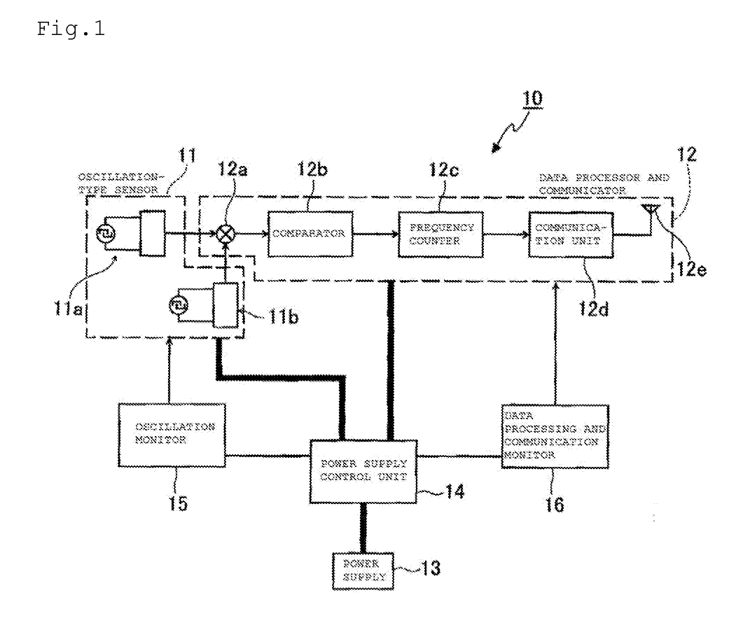

FIG. 1 is a diagram illustrating a configuration of a sensor device for sensor networks according to an embodiment of the present invention. As illustrated in FIG. 1, a sensor device for sensor networks 10 according to the embodiment of the present invention includes an oscillation-type sensor 11, a data processor and communicator 12, a power supply 13, and a power supply control unit 14.

The oscillation-type sensor 11 is a unit that oscillates with a mechanical vibrator, and an LC oscillator is provided in the unit. Since the oscillation-type sensor 11 is configured as an oscillator which uses a mechanical vibrator, the oscillation-type sensor 11 can output a change in a measurement value as a change in an oscillation frequency and have noise resistance.

In the embodiment illustrated in FIG. 1, the oscillation-type sensor 11 includes a measurement oscillator 11a and a reference oscillator 11b. The measurement oscillator 11a is attached to a measurement object, and a resonance frequency thereof changes when the measurement object deforms. By doing so, since a signal output from the measurement oscillator 11a and a reference signal output from the reference oscillator 11b are input to the data processor and communicator 12, information on the measurement object is obtained as a change in the resonance frequency. Since the change in the resonance frequency is obtained when the information on the measurement object is acquired, a gauge factor is remarkably improved.

A surface acoustic wave (SAW) sensor connected to a power supply line can be used as the oscillation-type sensor 11. When a conventional SAW sensor is used, an antenna and a SAW delay line form a tag, electric waves are transmitted from an external apparatus to the tag, and waves reflected from the tag are analyzed to detect a physical quantity applied to the tag. Since such a tag itself does not require a power supply for driving the same, the tag contributes to saving power. However, since an interrogator is necessary for transmitting and receiving electric waves to and from the tag, a SAW sensor that does not include a power supply system is not desirable. Moreover, since the SAW tag and the interrogator transmit and receive signals in one-to-one relation, the SAW sensor is not suitable for a sensor network.

Here, elements which use a piezoelectric effect such as a crystal oscillator and a piezoelectric thin film oscillator are preferred as the mechanical vibrator from the perspective of mechanical-to-electrical conversion.

The data processor and communicator 12 is a unit that processes a signal output from the oscillation-type sensor 11 and outputs data to an external apparatus. In the embodiment illustrated in FIG. 1, the data processor and communicator 12 includes a mixer 12a, a comparator 12b, a frequency counter 12c, a communication unit 12d, and an antenna 12e.

The mixer 12a receives the signal output from the oscillation-type sensor 11 to the measurement oscillator 11a and the signal output from the reference oscillator 11b and outputs a difference between both signals. That is, if a signal fₒᵤₜ1 output from the measurement oscillator 11a is expressed by the following equation (1):

fₒᵤₜ1=Oscillation frequency fₒ+Disturbance f_{d}+Frequency shift due to deformation Δf (1)

A reference frequency fₒᵤₜ2 is expressed by the following equation (2):

fₒᵤₜ2=Oscillation frequency fₒ+Disturbance f_{d} (2)

The output from the mixer 12a depends on the frequency shift due to deformation Δf.

The comparator 12b shapes a waveform output from the mixer 12a into a square wave. In this way, the output waveform can be processed as a digital waveform at a subsequent stage of the comparator 12b. Here, the frequency output from the mixer 12a corresponds to the frequency shift due to deformation Δf.

The frequency counter 12c counts the square wave output from the comparator 12b within a predetermined period as a digital waveform and outputs a count value to the communication unit 12d.

The communication unit 12d has a function of performing wireless communication connection with a relay station or a monitoring station via an external sensor network through the antenna 12e and outputs sensor information input from the frequency counter 12c via the communication connection as a digital signal. The communication unit 12d has a function of transmitting and receiving test packets to and from the external sensor network through the antenna 12e.

The power supply 13 supplies electric power to the oscillation-type sensor 11 and the data processor and communicator 12. The power supply 13 may be supplied with electric power from an external apparatus and may produce electric power by generating electric power using natural energy like energy harvesting. That is, when the sensor device for sensor networks 10 is installed outdoors, the sensor device for sensor networks 10 may be connected to a power feeding line (not illustrated) or the sensor device for sensor networks 10 may include a private power generator (not illustrated).

The power supply control unit 14 controls connection of a power supply line between the power supply 13 and the oscillation-type sensor 11 and connection of a power supply line between the power supply 13 and the data processor and communicator 12. In this way, the power supply 13 can drive the oscillation-type sensor 11 prior to the other units by supplying electric power to the oscillation-type sensor 11 only and start supplying electric power to the data processor and communicator 12 depending on the state of the oscillation-type sensor 11.

As described above, in the embodiment of the present invention, the power supply control unit 14 drives the oscillation-type sensor 11 prior to the other units by connecting the power supply line between the power supply 13 and the oscillation-type sensor 11 and then connects the power supply line between the power supply 13 and the data processor and communicator 12. Therefore, since electric power is supplied to the data processor and communicator 12 after the oscillation of the oscillation-type sensor 11 is stabilized, it is not necessary to supply electric power to the data processor and communicator 12 for a period required for stabilizing the oscillation-type sensor 11. The stability of the oscillation-type sensor 11 is a factor that determines the accuracy of the sensor device for sensor networks 10. Therefore, it is possible to maintain accuracy and to save power.

Since the mixer 12a, the comparator 12b, the frequency counter 12c, and the communication unit 12d that form the data processor and communicator 12 are configured as a semiconductor amplification circuit, the data processor and communicator 12 does not require a warming-up operation and the activation time thereof is very short. Due to this, the activation time of the data processor and communicator 12 is negligibly short as compared to a period required for activating the oscillation-type sensor 11 and stabilizing the oscillation thereof. Therefore, it is possible to suppress power consumed by the oscillation-type sensor 11.

### [Sensor Device for Sensor Networks According to More Preferable Embodiment]

As illustrated in FIG. 1, the sensor device for sensor networks 10 preferably includes any one of or both of the oscillation monitor 15 and the data processing and communication monitor 16.

The oscillation monitor 15 is a monitoring unit that monitors an oscillation state of the oscillation-type sensor 11. The oscillation monitor 15 monitors one or more elements of waves such as a frequency, a wavelength, an amplitude, and the like of the signal output from the oscillation-type sensor 11, for example, and determines that the oscillation is stabilized when one or more elements of the waves fall within a predetermined range. In this manner, the power supply line between the power supply 13 and the data processor and communicator 12 is connected according to a monitoring state of the oscillation-type sensor 11 obtained by the oscillation monitor 15 (that is, when the oscillation of the oscillation-type sensor 11 is stabilized). In order to determine stability of oscillation, it is necessary to remove a time-series change due to disturbance elements. Therefore, in the embodiment of the present invention, disturbance elements which can be regarded to be uniform in a chip-level range such as temperature, humidity, and the like under an environment in which the sensor device for sensor networks 10 is disposed can be removed by the mixer 12a mixing the output of the measurement oscillator 11a and the output of the reference oscillator 11b.

In the embodiment illustrated in FIG. 1, the oscillation monitor 15 is provided as a unit separate from the power supply control unit 14. However, the oscillation monitor 15 may be included in the power supply control unit 14. Moreover, for example, the power supply line between the power supply 13 and the data processor and communicator 12 may be connected when a predetermined period has elapsed after the power supply line between the power supply 13 and the oscillation-type sensor 11 is connected. The oscillation-type sensor 11 oscillates stably when a predetermined period has elapsed after the oscillation-type sensor 11 is driven prior to the other units. Moreover, by estimating the stability over time, it is possible to suppress power consumed by the oscillation monitor 15. The elapse of the predetermined period may be determined by counting the number of oscillations of the oscillation-type sensor 11.

The oscillation monitor 15 may monitor any one of the oscillation state of the measurement oscillator 11a and the oscillation state of the reference oscillator 11b. However, since the measurement oscillator 11a measures a physical quantity of a measurement object, it may be difficult for the physical quantity to fall within a predetermined range under a given environment. Due to this, the oscillation monitor 15 preferably monitors the oscillation state of the reference oscillator 11b.

The data processing and communication monitor 16 is another monitoring unit different from an oscillation monitor for monitoring an activation state of the data processor and communicator 12. The data processing and communication monitor 16 is a unit that checks the activation state of the data processor and communicator 12 and a communication connection state with the sensor network.

The data processing and communication monitor 16 preferably transmits and receives test packets to and from an external apparatus (that is, the sensor network) to secure a communication path, and then, the power supply control unit 14 may activate the mixer 12a, the comparator 12b, and the frequency counter 12c. This is because, during transmission/reception of test packets, it is highly likely that securing a communication path requires a considerable period of time due to unexpected factors of the external apparatus such as the sensor network.

The power supply control unit 14 may determine the activation order of the respective units on the basis of the magnitude of power consumed by the mixer 12a, the comparator 12b, the frequency counter 12c, and the communication unit 12d in order to save power. In this case, when it is expected that transmission/reception of test packets by the communication unit 12d requires a considerable period of time, the communication unit 12d may be activated first, and then, the remaining non-activated units may be activated sequentially on the basis of the magnitude of the activation period and the power consumption of the mixer 12a, the comparator 12b, and the frequency counter 12c.

The data processing and communication monitor 16 may predict the period required for activating the mixer 12a, the comparator 12b, the frequency counter 12c, and the communication unit 12d and may determine that the activation of the data processor and communicator 12 and the formation of the communication path are completed when this period has elapsed.

The data processing and communication monitor 16 instructs the data processor and communicator 12 to start performing data communication with the sensor network when the activation state of the data processor and communicator 12 and the communication connection state with the sensor network are confirmed by any of the above-described method.

### [Sensor Network]

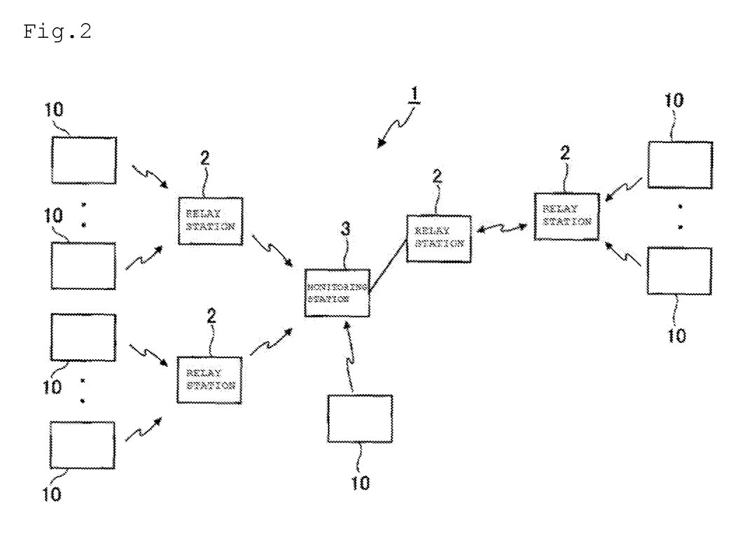

FIG. 2 is a diagram illustrating an example of a sensor network constructed using the sensor device for sensor networks according to the embodiment of the present invention. As illustrated in FIG. 2, for example, a sensor network 1 includes one or more relay stations 2 and one or more monitoring stations 3 and is constructed so as to be able to acquire sensor information from the sensor device for sensor networks 10. The monitoring station 3 is also referred to as an interrogating station. Only one of the relay station 2 and the monitoring station 3 may be provided. When the relay station 2 only is provided, the relay station 2 also serves as the monitoring station 3. In the sensor network 1, it is assumed that the sensor device for sensor networks 10 performs wireless communication. However, the sensor device for sensor networks 10 may perform communication via cables. The communication between the relay stations 2 and the communication between the relay station 2 and the monitoring station 3 may be performed via cables or wirelessly.

The monitoring station 3 can acquire sensor information from the sensor device for sensor networks 10 via the relay station 2 and acquire information of the environment in which the sensor device for sensor networks 10 is installed, the structures of a transportation system, and building structures, and other measurement objects. The relay station 2 which also serves as the monitoring station 3 can also acquire sensor information.

In this case, in each sensor device for sensor networks 10, the power supply control unit 14 may connect the power supply line between the power supply 13 and the oscillation-type sensor 11 at a determined date and time. Alternatively, a trigger may be transmitted from the monitoring station 3 or the relay station 2 to the sensor device for sensor networks 10 to activate the power supply control unit 14 of the sensor device for sensor networks 10 so that the power supply control unit 14 connects the power supply line between the power supply 13 and the oscillation-type sensor 11. In this case, only a portion of a reception function may be activated using a beacon including ID (identification) as an electric wave rather than using a complex trigger so that the ID of the beacon can be read. In this way, the power consumption is suppressed greatly as compared to the conventional specifications.

### [Method for Transmitting Data to Sensor Network]

A method for transmitting data to a sensor network which uses the sensor device for sensor networks 10 illustrated in FIG. 1 will be described.

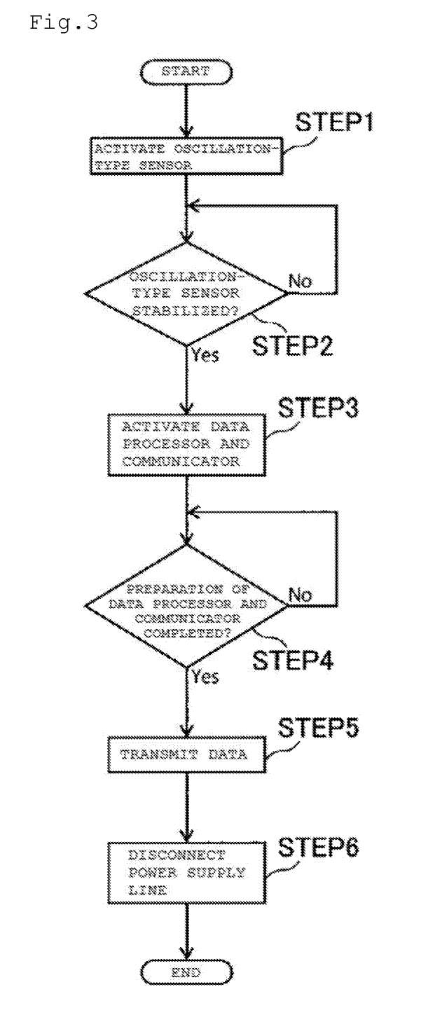

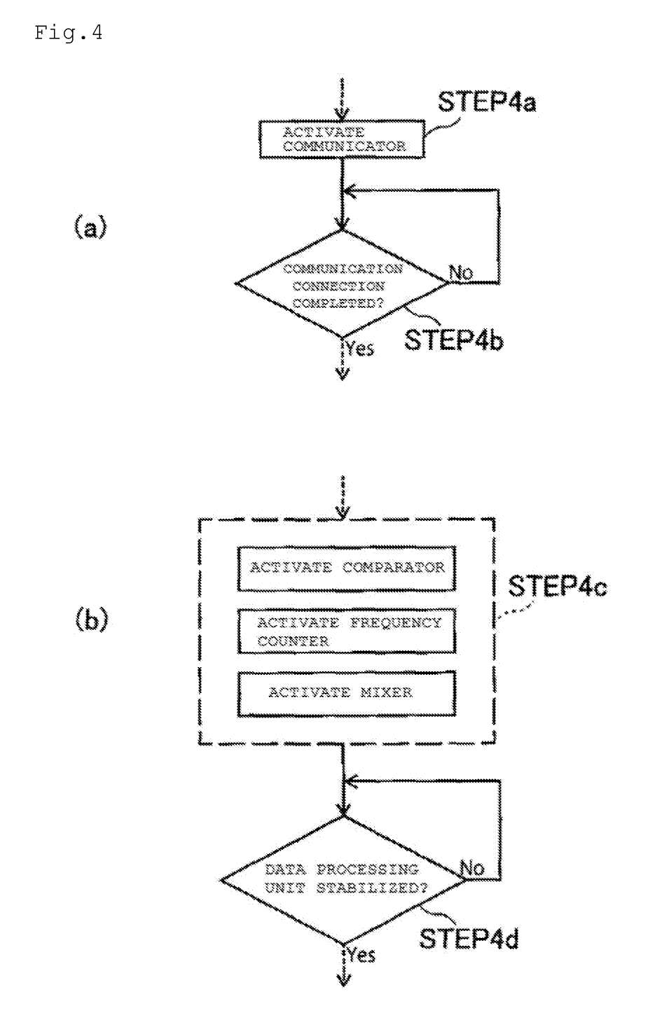

FIG. 3 is a flowchart of a method for transmitting data to a sensor network according to an embodiment of the present invention, FIG. 4(a) illustrates a portion of STEP4 “Preparation of data processor and communicator completed?” illustrated in FIG. 3, and FIG. 4(b) is a diagram illustrating a remaining portion thereof.

As described above, the sensor device for sensor networks 10 allows the power supply control unit 14 to connect the power supply line between the power supply 13 and the oscillation-type sensor 11 at a determined data and time or upon receiving a trigger such as an electric wave of a beacon. In this way, the oscillation-type sensor 11 is activated (STEP1).

Subsequently, this loop is repeated until the oscillation of the oscillation-type sensor 11 is stabilized (STEP2: Yes). Whether the oscillation of the oscillation-type sensor 11 is stabilized is determined by the oscillation monitor 15 on the basis of whether one or more elements of the wave of the output signal of the oscillation-type sensor 11 fall within a predetermined range or a predetermined period has elapsed from the start of activation of the oscillation-type sensor 11.

When “Yes” is obtained in STEP2, the power supply control unit 14 connects the power supply line between the power supply 13 and the data processor and communicator 12. In this way, the data processor and communicator 12 is activated (STEP3).

Subsequently, this loop is repeated until preparation of the data processor and communicator 12 is completed (STEP4: Yes). Whether the preparation of the data processor and communicator 12 is completed is determined by the data processing and communication monitor 16 on the basis of whether securing of a communication path by transmission/reception of test packets is completed and whether the activation of the mixer 12a, the comparator 12b, and the frequency counter 12c is completed, or whether a predetermined period has elapsed from the start of activation of the data processor and communicator 12.

One of specific processes of STEP4 basically includes activation of the communication unit 12d (STEP4a) and determination on completion of communication connection (STEP4b) as illustrated in FIG. 4(a). The communication unit 12d transmits test packets to the relay station 2 of the sensor network 1 or the monitoring station 3 via the monitoring station 3 and checks response test packets and thereby determine whether establishment of a communication path is completed.

Another specific process of STEP4 includes activating the mixer 12a, the comparator 12b, and the frequency counter 12c in a determined order (STEP4c) and determining whether a data processing unit including these units is stabilized (STEP4d). The determination loop is repeated when the data processing unit is not stabilized. Moreover, it is not always necessary to determine the stability of the data processing unit, and the determination loop may be cleared when a predetermined period has elapsed from the start of activation of any one of the units of the data processing unit.

When “Yes” is obtained in STEP4, the data processor and communicator 12 processes the sensor signal output from the oscillation-type sensor 11 and transmits the processed signal to the relay station 2 or the monitoring station 3 via the sensor network.

After that, the power supply control unit 14 disconnects the power supply line between the power supply 13 and the oscillation-type sensor 11 and the power supply line between the power supply 13 and the data processor and communicator 12 (STEP6). In this way, the sensor device for sensor networks 10 enters a sleep state again.

In the method for transmitting data to the sensor network according to the embodiment of the present invention, the sensor device for sensor networks 10 including the oscillation-type sensor 11 that oscillates with a mechanical vibrator and the data processor and communicator 12 that processes a signal output from the oscillation-type sensor 11 to transmit the signal to an external apparatus transmits data to the sensor network. First, the power supply control unit 14 connects the power supply line between the power supply 13 and the oscillation-type sensor 11 to activate the oscillation-type sensor 11. Subsequently, when the oscillation monitor 15 confirms that the oscillation state of the oscillation-type sensor 11 is stabilized or when the oscillation state of the oscillation-type sensor 11 is stabilized with the elapse of a predetermined period from the activation of the oscillation-type sensor 11, the power supply control unit 14 connects the power supply line between the power supply 13 and the data processor and communicator 12. In this way, the data processor and communicator 12 is activated. After that, after the data processor and communicator 12 is activated stably and a communication connection via the sensor network is confirmed, the data processor and communicator 12 processes the signal output from the oscillation-type sensor 11 and transmits data to the sensor network. When a predetermined period has elapsed or a response is received from the sensor network 1, the power supply control unit 14 disconnects all power supply lines.

In this manner, even when the sensor device for sensor networks 10 is activated intermittently, the sensor information is transmitted to the relay station 2 or the monitoring station 3 after the oscillation of the oscillation-type sensor 11 is stabilized. Therefore, it is possible to meet demands to save power and maintain accuracy, which are difficult to achieve simultaneously.

In this way, the state of various building and construction infrastructures such as structures of a transportation system can be obtained at an appropriate time and necessary measures can be taken at a necessary timing.

### [Method for Transmitting Data to Sensor Network According to Another Embodiment]

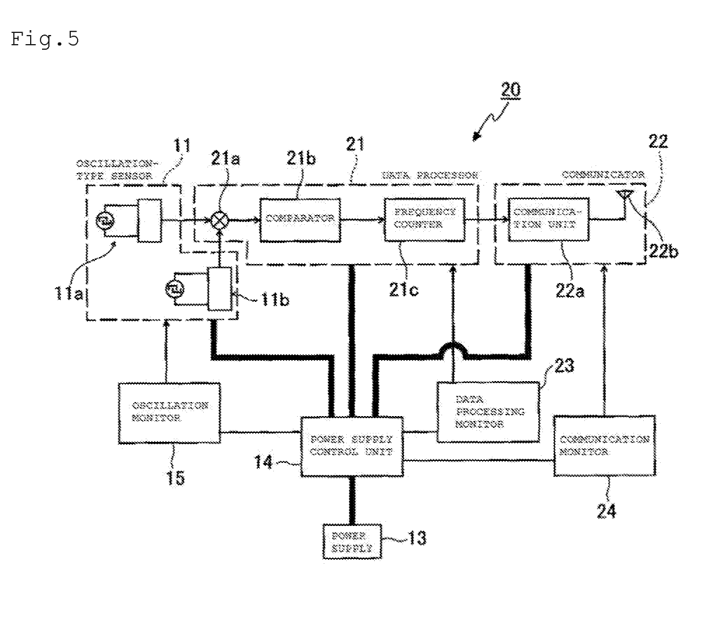

The sensor device for sensor networks 10 according to the embodiment of the present invention is not limited to the configuration illustrated in FIG. 1. FIG. 5 is a diagram illustrating a configuration of the sensor device for sensor networks according to the embodiment of the present invention, the configuration being different from that illustrated in FIG. 1. In a sensor device for sensor networks 20 illustrated in FIG. 5, the same or corresponding units as those of FIG. 5 will be denoted by the same reference numerals.

The sensor network system 20 includes a data processor 21 and a communicator 22 instead of the data processor and communicator 12 unlike FIG. 1. The sensor network system 20 includes an oscillation-type sensor 11, a power supply 13, and a power supply control unit 14 similary to FIG. 1.

The data processor 21 processes a signal output from the oscillation-type sensor 11 and outputs the signal to the communicator 22. In the embodiment illustrated in FIG. 5, the data processor 21 includes a mixer 21a, a comparator 21b, and a frequency counter 21c. These units have the same functions as the units illustrated in FIG. 1. The frequency counter 12c counts the square wave output from the comparator 21b within a predetermined period as a digital waveform and outputs a count value to the communicator 22.

The communicator 22 transmits data input from the data processor 21 to an external apparatus. The communicator 22 includes a communication unit 22a and an antenna 22b, and these units have the same functions as the units illustrated in FIG. 1.

The power supply 13 supplies electric power to the oscillation-type sensor 11, the data processor 21, and the communicator 22. The source of the power supply 13 is the same as that illustrated in FIG. 1.

The power supply control unit 14 controls connection between a power supply line between the power supply 13 and the oscillation-type sensor 11, connection between a power supply line between the power supply 13 and the data processor 21, and connection of a power supply line between the power supply 13 and the communicator 22. In this way, the power supply 13 can drive the oscillation-type sensor 11 prior to the other units by supplying electric power to the oscillation-type sensor 11 only, start supplying electric power to any one of the data processor 21 and the communicator 22 depending on the state of the oscillation-type sensor 11, and start supplying electric power to the remaining unit.

As described above, in the embodiment of the present invention, the power supply control unit 14 drives the oscillation-type sensor 11 prior to the other units by connecting the power supply line between the power supply 13 and the oscillation-type sensor 11, and then, connects any one of the power supply line between the power supply 13 and the data processor 21 and the power supply line between the power supply 13 and the communicator 22, and subsequently, connects the remaining power supply line. Therefore, after the oscillation of the oscillation-type sensor 11 is stabilized, the power supply control unit 14 supplies electric power to any one of the data processor 21 and the communicator 22 and supplies electric power to the other one of the data processor 21 and the communicator 22, which is not activated. Due to this, it is not necessary to supply electric power to the data processor 21 and the communicator 22 for a period required for stabilizing the oscillation-type sensor 11. The stability of the oscillation-type sensor 11 is a factor that determines the accuracy of the sensor device for sensor networks 10. Therefore, it is possible to maintain accuracy and to save power. Moreover, since any one of the data processor 21 and the communicator 22 is activated prior to the other unit, it is possible to save much power.

The sensor device for sensor networks 20 preferably includes any one of or both of the data processing monitor 23 and the communication monitor 24 and the oscillation monitor 15 instead of the data processing and communication monitor 16 illustrated in FIG. 1.

In the embodiment illustrated in FIG. 5, the oscillation monitor 15 is provided as a unit separate from the power supply control unit 14. However, the oscillation monitor 15 may be included in the power supply control unit 14. Moreover, for example, any one of the power supply line between the power supply 13 and the data processor 21 and the power supply line between the power supply 13 and the communicator 22 may be connected when a predetermined period has elapsed after the power supply line between the power supply 13 and the oscillation-type sensor 11 is connected. The oscillation-type sensor 11 oscillates stably when a predetermined period has elapsed after the oscillation-type sensor 11 is driven prior to the other units. Moreover, by estimating the stability over time, it is possible to suppress power consumed by the oscillation monitor 15. The elapse of the predetermined period may be determined by counting the number of oscillations of the oscillation-type sensor 11.

The data processing monitor 23 is a monitor for monitoring the activation state of the data processor 21 and is another monitoring unit different from the oscillation monitor 15. The data processing monitor 23 checks the activation state of the data processor 21.

The communication monitor 24 is a monitor for monitoring the activation state of the communicator 22 and is another monitoring unit different from the oscillation monitor 15. The communication monitor 24 checks a communication connection state with the sensor network.

For example, the communication monitor 24 is provided in the sensor device for sensor networks 20. In this case, the power supply control unit 14 drives the oscillation-type sensor 11 prior to the other units by connecting the power supply line between the power supply 13 and the oscillation-type sensor 11, and then, connects the power supply line between the power supply 13 and the communicator 22. The communicator 22 transmits and receives test packets to and from an external apparatus (that is, the sensor network) and the communication monitor 24 checks securing of a communication path. After that, the power supply control unit 14 connects the power supply line between the power supply 13 and the data processor 21 to activate the mixer 21a, the comparator 21b, and the frequency counter 21c. This is because, during transmission/reception of test packets, it is highly likely that securing a communication path requires a considerable period of time due to unexpected factors of the external apparatus such as the sensor network.

In contrast, the data processing monitor 23 is provided in the sensor device for sensor networks 20. In this case, the power supply control unit 14 drives the oscillation-type sensor 11 prior to the other units by connecting the power supply line between the power supply 13 and the oscillation-type sensor 11, and then, connects the power supply line between the power supply 13 and the data processor 21. By doing so, the mixer 21a, the comparator 21b, and the frequency counter 21c are activated. When the data processing monitor 23 confirms the activation state of the data processor 21 or when a predetermined period has elapsed, the power supply line between the power supply 13 and the communicator 22 is connected. The communicator 22 transmits and receives test packets to and from an external apparatus (that is, the sensor network) and the communication monitor 24 checks securing of a communication path. This is effective when the product between the period and the power required for activating the data processor 21 is larger than the product between the period and the power required for activating the communicator 22.

### [Method for Transmitting Data to Sensor Network According to Another Embodiment]

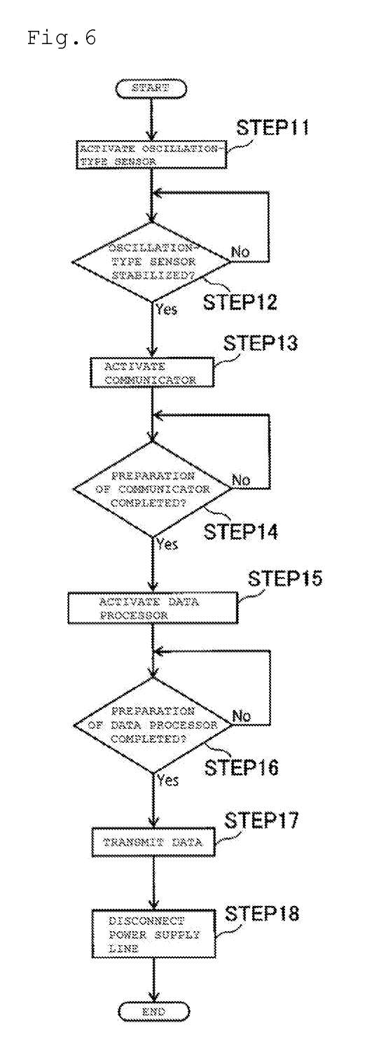

FIG. 6 is a flowchart of the method for transmitting data to the sensor network according to the embodiment of the present invention, the flowchart being different from that illustrated in FIG. 3. A method for transmitting data to the sensor network which uses the sensor device for sensor networks 20 illustrated in FIG. 5 will be described.

As described above, the sensor device for sensor networks 10 allows the power supply control unit 14 to connect the power supply line between the power supply 13 and the oscillation-type sensor 11 at a determined data and time or upon receiving a trigger such as an electric wave of a beacon. In this way, the oscillation-type sensor 11 is activated (STEP11).

Subsequently, this loop is repeated until the oscillation of the oscillation-type sensor 11 is stabilized (STEP12: Yes). Whether the oscillation of the oscillation-type sensor 11 is stabilized is determined by the oscillation monitor 15 on the basis of whether one or more elements of the wave of the output signal of the oscillation-type sensor 11 fall within a predetermined range or a predetermined period has elapsed from the start of activation of the oscillation-type sensor 11.

When “Yes” is obtained in STEP12, the power supply control unit 14 connects the power supply line between the power supply 13 and the communicator 22. In this way, the communicator 22 is activated (STEP13).

Subsequently, this loop is repeated until preparation of the communicator 22 is completed (STEP14: Yes). Whether the preparation of the data processor and communicator 12 is completed is determined on the basis of whether securing of a communication path by transmission/reception of test packets is completed and whether a predetermined period has elapsed from the start of activation of the communicator 22. The communication unit 22a transmits test packets to the relay station 2 of the sensor network 1 or the monitoring station 3 via the monitoring station 3 and checks response test packets and thereby determine whether establishment of a communication path is completed.

When “Yes” is obtained in STEP14, the power supply control unit 14 connects the power supply line between the power supply 13 and the data processor 21. In this way, the data processor 21 is activated (STEP15).

Subsequently, this loop is repeated until preparation of the data processor 21 is completed (STEP16: Yes). Whether the preparation of the data processor 21 is completed is determined by the data processing monitor 23 activating the mixer 21a, the comparator 21b, and the frequency counter 21c in a determined order and determining whether the data processor 21 including these units is stabilized. The determination loop is repeated when the data processing unit is not stabilized. Moreover, it is not always necessary to determine the stability of the data processor 21, and the determination loop may be cleared when a predetermined period has elapsed from the start of activation of any one of the units of the data processing unit.

When “Yes” is obtained in STEP16, the data processor 21 processes the sensor signal output from the oscillation-type sensor 11, outputs the processed signal to the communicator 22, and transmits the same from the communicator 22 to the relay station 2 or the monitoring station 3 via the sensor network (STEP17).

After that, the power supply control unit 14 disconnects the power supply line between the power supply 13 and the oscillation-type sensor 11, and the power supply line between the power supply 13 and the data processor 21, and the power supply line between the power supply 13 and the communicator 22 (STEP18). In this way, the sensor device for sensor networks 20 enters a sleep state again.

In the method for transmitting data to the sensor network according to the embodiment of the present invention, the sensor device for sensor networks 20 including the oscillation-type sensor 11 that oscillates with a mechanical vibrator, the data processor 21 that processes a signal output from the oscillation-type sensor 11, and the communicator 22 that transmits the data input from the data processor 21 to an external apparatus transmits data to the sensor network. First, the power supply control unit 14 connects the power supply line between the power supply 13 and the oscillation-type sensor 11 to activate the oscillation-type sensor 11. Subsequently, when the oscillation monitor 15 confirms that the oscillation state of the oscillation-type sensor 11 is stabilized or when the oscillation state of the oscillation-type sensor 11 is stabilized with the elapse of a predetermined period from the activation of the oscillation-type sensor 11, the power supply control unit 14 connects the power supply line between the power supply 13 and the communicator 22. In this way, the communicator 22 is activated. After that, it is determined that a communication path is established when securing of a communication connection via the sensor network is confirmed or when a predetermined period has elapsed after the communicator 22 is activated, and the power supply control unit 14 connects the power supply line between the power supply 13 and the data processor 21. In this way, the data processor 21 is activated. When the data processor 21 is stabilized, the data processor 21 processes the signal output from the oscillation-type sensor 11 and transmits data to the sensor network via the communicator 22. When a predetermined period has elapsed or a response is received from the sensor network 1, the power supply control unit 14 disconnects all power supply lines.

In this manner, even when the sensor device for sensor networks 10 is activated intermittently, the sensor information is transmitted to the relay station 2 or the monitoring station 3 after the oscillation of the oscillation-type sensor 11 is stabilized. Therefore, it is possible to meet demands to save power and maintain accuracy, which are difficult to achieve simultaneously. Moreover, since the data processor 21 and the communicator 22 are activated separately, it is possible to save much power.

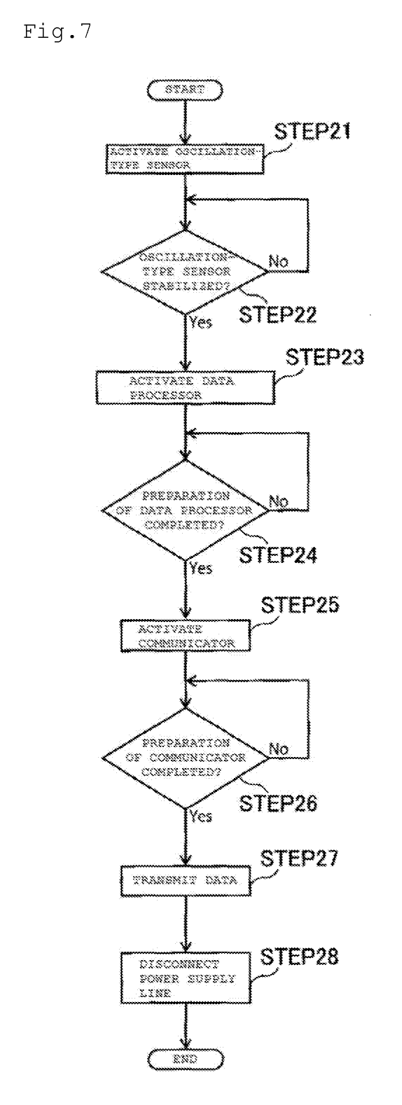

FIG. 7 is a flowchart of the method for transmitting data to the sensor network according to the embodiment of the present invention, the flowchart being different from those illustrated in FIGS. 3 and 6. A method for transmitting data to a sensor network which uses the sensor device for sensor networks 20 illustrated in FIG. 5 will be described. STEP21 to STEP22 are the same as STEP11 to STEP12 in FIG. 6.

When “Yes” is obtained in STEP22, the power supply control unit 14 connects the power supply line between the power supply 13 and the data processor 21. In this way, the data processor 21 is activated (STEP23).

Subsequently, this loop is repeated until preparation of the data processor 21 is completed (STEP24: Yes). Whether the preparation of the data processor 21 is completed is determined by the data processing monitor 23 activating the mixer 21a, the comparator 21b, and the frequency counter 21c in a determined order and determining whether the data processor 21 including these units is stabilized. The determination loop is repeated when the data processing unit is not stabilized. Moreover, it is not always necessary to determine the stability of the data processor 21, and the determination loop may be cleared when a predetermined period has elapsed from the start of activation of any one of the units of the data processor 21.

When “Yes” is obtained in STEP24, the power supply control unit 14 connects the power supply line between the power supply 13 and the communicator 22. In this way, the communicator 22 is activated (STEP25).

Subsequently, this loop is repeated until preparation of the communicator 22 is completed (STEP26: Yes). Whether the preparation of the communicator 22 is completed is determined by the communication monitor 24 on the basis of whether securing of a communication path by transmission/reception of test packets is completed and whether a predetermined period has elapsed from the start of activation of the communicator 22. The communication unit 22a transmits test packets to the relay station 2 of the sensor network 1 or the monitoring station 3 via the monitoring station 3 and checks response test packets and thereby determine whether establishment of a communication path is completed.

When “Yes” is obtained in STEP26, the data processor 21 processes the sensor signal output from the oscillation-type sensor 11, outputs the processed signal to the communicator 22, and transmits the same from the communicator 22 to the relay station 2 or the monitoring station 3 via the sensor network (STEP27).

After that, the power supply control unit 14 disconnects the power supply line between the power supply 13 and the oscillation-type sensor 11, and the power supply line between the power supply 13 and the data processor 21, and the power supply line between the power supply 13 and the communicator 22 (STEP28). In this way, the sensor device for sensor networks 20 enters a sleep state again.

In the method for transmitting data to the sensor network according to the embodiment of the present invention, the sensor device for sensor networks 20 including the oscillation-type sensor 11 that oscillates with a mechanical vibrator, the data processor 21 that processes a signal output from the oscillation-type sensor 11, and the communicator 22 that transmits the data input from the data processor 21 to an external apparatus transmits data to the sensor network. First, the power supply control unit 14 connects the power supply line between the power supply 13 and the oscillation-type sensor 11 to activate the oscillation-type sensor 11. Subsequently, when the oscillation monitor 15 confirms that the oscillation state of the oscillation-type sensor 11 is stabilized or when the oscillation state of the oscillation-type sensor 11 is stabilized with the elapse of a predetermined period from the activation of the oscillation-type sensor 11, the power supply control unit 14 connects the power supply line between the power supply 13 and the data processor 21. In this way, the data processor 21 is activated. After that, it is determined that the data processor 21 is stabilized when the stability of the data processor 21 is confirmed or a predetermined period has elapsed after the data processor 21 is activated, and the power supply control unit 14 connects the power supply line between the power supply 13 and the communicator 22. In this way, the communicator 22 is activated. It is determined that a communication path is established when securing of a communication connection via the sensor network is confirmed or when a predetermined period has elapsed after the communicator 22 is activated, and the data processor 21 processes the signal output from the oscillation-type sensor 11 and transmits data to the sensor network via the communicator 22. When a predetermined period has elapsed or a response is received from the sensor network 1, the power supply control unit 14 disconnects all power supply lines.

In this manner, even when the sensor device for sensor networks 10 is activated intermittently, the sensor information is transmitted to the relay station 2 or the monitoring station 3 after the oscillation of the oscillation-type sensor 11 is stabilized. Therefore, it is possible to meet demands to save power and maintain accuracy, which are difficult to achieve simultaneously. Moreover, since the data processor 21 and the communicator 22 are activated separately, it is possible to save much power.

The embodiment of the present invention is not limited to the above-described matters but can be appropriately changed depending on a place in which the sensor device for sensor networks is disposed and the use of information by sensors. For example, when the elapsed time is monitored, the number of oscillations of the oscillation-type sensor may be counted and the counted number may be used as a timer.

### REFERENCE SIGNS LIST

1: Sensor network
2: Relay station
3: Monitoring station
10, 20: Sensor device for sensor networks
11: Oscillation-type sensor
11a: Measurement oscillator
11b: Reference oscillator
12: Data processor and communicator
12a: Mixer
12b: Comparator
12c: Frequency counter
12d: Communication unit
12e: Antenna
13: Power source
14: Power supply control unit
15: Oscillation monitor
16: Data processing and communication monitor
21: Data processor
21a: Mixer
21b: Comparator
21c: Frequency counter
22: Communicator
22a: Communication unit
22b: Antenna
23: Data processing monitor
24: Communication monitor

1. A sensor device for sensor networks, comprising:
an oscillation-type sensor that oscillates with a mechanical vibrator;
a data processor and communicator that processes a signal output from the oscillation-type sensor and transmits data to an external apparatus;
a power supply that supplies electric power to the oscillation-type sensor and the data processor and communicator; and
a power supply control unit that controls connection of a power supply line between the power supply and the oscillation-type sensor and connection of a power supply line between the power supply and the data processor and communicator, wherein
the power supply control unit connects the power supply line between the power supply and the oscillation-type sensor and then connects the power supply line between the power supply and the data processor and communicator.

2. The sensor device for sensor networks according to claim 1, further comprising:
a monitoring unit that monitors an oscillation state of the oscillation-type sensor, wherein
the power supply control unit connects the power supply line between the power supply and the data processor and communicator according to a monitoring state obtained by the monitoring unit.

3. The sensor device for sensor networks according to claim 1, further comprising:
another monitoring unit that monitors an activation state of the data processor and communicator, wherein
the other monitoring unit instructs the data processor and communicator to start performing data communication with a sensor network when an activation state of the data processor and communicator and a communication connection state with the sensor network are confirmed.

4. The sensor device for sensor networks according to claim 1, wherein
upon receiving an instruction via a sensor network, the power supply control unit starts connecting the power supply line between the power supply and the oscillation-type sensor.

5. The sensor device for sensor networks according to claim 1, wherein
the data processor and communicator includes a data processor that processes the signal output from the oscillation-type sensor and a communicator that transmits data input from the data processor to the external apparatus, and
the power supply control unit controls the power supply line between the power supply and the data processor and the power supply line between the power supply and the communicator separately.

6. The sensor device for sensor networks according to claim 1, wherein
the oscillation-type sensor is a surface acoustic wave sensor.

7. The sensor device for sensor networks according to claim 1, wherein
the mechanical vibrator is a crystal oscillator or a piezoelectric thin film oscillator.

8. A method for transmitting data to a sensor network, comprising:
when a sensor device for sensor networks including an oscillation-type sensor that oscillates with a mechanical vibrator and a data processor and communicator that processes a signal output from the oscillation-type sensor and transmits the signal to an external apparatus transmits data to a sensor network,
activating the oscillation-type sensor;
activating the data processor and communicator after oscillation of the oscillation-type sensor is stabilized, and
allowing the data processor and communicator to process the signal output from the oscillation-type sensor to transmit the data to the sensor network when an activation state of the data processor and communicator and a communication connection state with the sensor network are confirmed.

9. A method for transmitting data to a sensor network, comprising:
when a sensor device for sensor networks including an oscillation-type sensor that oscillates with a mechanical vibrator, a data processor that processes a signal output from the oscillation-type sensor, and a communicator that transmits data input from the data processor to an external apparatus transmits data to a sensor network,
activating the oscillation-type sensor;
activating any one of the data processor and the communicator after oscillation of the oscillation-type sensor is stabilized; and
activating any one of the communicator and the data processor which is not activated when an activation state of any one of the data processor and the communicator is confirmed and allowing the data processor to process the signal output from the oscillation-type sensor to transmit the data to the sensor network via the communicator when the activation is confirmed.
